(19) United States
(12) Patent Application Publication
(10) Pub. No.: US 2011/0140719 A1
(43) Pub. Date: Jun. 16, 2011

(54) METHOD OF MONITORING SEMICONDUCTOR PROCESS

(75) Inventors: HO-KI LEE, Anyang-si (KR); Kye-Hyun Baek, Suwon-si (KR); Yong-Jin Kim, Suwon-si (KR)

(73) Assignee: Samsung Electronics Co., Ltd.

(21) Appl. No.: 12/872,574

(22) Filed: Aug. 31, 2010

(30) Foreign Application Priority Data
Dec. 14, 2009 (KR) 10-2009-0124213

(51) Int. Cl. G01R 27/26

(52) U.S. Cl. 324/679

(57) ABSTRACT

A method of monitoring a semiconductor process is provided. The method includes preparing a process chamber including first and second electrodes spaced apart from and facing each other, and connecting the first electrode to a ground and connecting the second electrode to a radio frequency power source. An impedance in the process chamber is measured using a voltage value and a current value at the second electrode. The consumption amount of consumables in the process chamber is checked using the impedance. Varied process conditions are adjusted within an initial set range.

### PRIORITY STATEMENT

This application claims the benefit of priority under 35 U.S.C. §119 from Korean Patent Application No. 10-2009-0124213, filed on Dec. 14, 2009, the contents of which are hereby incorporated herein by reference in its entirety.

### BACKGROUND

1. Field

Example embodiments relate to a method of monitoring a semiconductor process, and more particularly, to a method of monitoring the consumption amount of consumables in semiconductor equipment used in a semiconductor process.

2. Description of Related Art

As semiconductor memory devices are highly integrated, it is important to uniformly maintain conditions of a semiconductor process to improve reliability. That is, it is essential to uniformly maintain the process conditions in equipment used in the semiconductor process. However, a large number of consumables exist in the semiconductor equipment, and thus, the process conditions may be frequently varied due to the consumption amount of the consumables. Such a variation in process conditions results in a drift phenomenon of the process. Therefore, a method of monitoring the consumption amount of the consumables is needed.

### SUMMARY

Example embodiments provide a method of monitoring the consumption amount of consumables in equipment for a semiconductor process, which can solve problems of a conventional art such as a drift phenomenon of a process due to a variation in process conditions.

Example embodiments also provide a method of monitoring equipment capable of maintaining process conditions varied by the consumption amount of the consumables at initial process conditions.

Example embodiments are directed to a method of monitoring a semiconductor process. In the method, a process chamber including first and second electrodes spaced apart from and facing each other is prepared. The first electrode is connected to a ground and the second electrode is connected to a radio frequency power. An impedance in the process chamber is measured using a voltage value and a current value at the second electrode. The consumption amount of consumables in the process chamber is measured using the impedance.

In some embodiments, an inductor and a resistor may be electrically connected between the second electrode and the radio frequency power.

According to another embodiment, after measuring the impedance, a capacitance of the process chamber may be calculated using the impedance, and the consumption amount of the consumables may be checked using the capacitance.

According to still another embodiment, calculating the capacitance may include acquiring a phase of a voltage applied to the process chamber, a resistance of the resistor, an inductive reactance of the inductor, and a capacitive reactance between the first and second electrodes; and calculating the capacitance using a difference between the inductive reactance and the capacitive reactance, the phase of the voltage, the resistance, and a frequency of the current.

According to yet another embodiment, calculating the capacitance may include, when the phase of the voltage applied to the process chamber is 90° or 270°, the resistance is 0Ω to 2Ω, and the frequency of the current is 2 MHz or less, approximating the resistance to 0; and approximating the difference between the reactive reactance and the capacitive reactance to the capacitive reactance to calculate the capacitance.

Example embodiments are also directed to a method of monitoring a semiconductor process. In the method, a process chamber including first and second electrodes spaced apart from and facing each other is provided. The first electrode is connected to a ground and the second electrode is connected to a radio frequency power. An impedance in the process chamber is measured using a voltage value and a current value at the second electrode. The consumption amount of consumables in the process chamber is checked using the impedance. Process conditions varied according to the consumption amount of the consumables are measured. The varied conditions are measured within an initial set range.

According to some embodiments, measuring the process conditions varied according to the consumption amount of the consumables may include setting a first reference graph in which a variation in impedance according to the consumption amount of the consumables is represented as a linear function; setting a second reference graph in which process conditions varied according to the consumption amount of the consumables are represented as a linear function; and measuring a variation in process conditions according to the consumption amount of the consumables using the first and second reference graphs.

According to another embodiment, after measuring the impedance, the consumables may be exchanged when the impedance departs from the set range.

According to still another embodiment, an inductor and a resistor may be electrically connected between the second electrode and the radio frequency power.

According to yet another embodiment, after measuring the impedance, a capacitance of the process chamber may be calculated using the impedance; and the consumption amount of the consumables may be checked using the capacitance.

According to yet another embodiment, calculating the capacitance may include acquiring a phase of a voltage applied to the process chamber, a resistance of the resistor, an inductive reactance of the inductor, and a capacitive reactance between the first and second electrodes; and calculating the capacitance using a difference between the inductive reactance and the capacitive reactance, the phase of the voltage, the resistance, and a frequency of the current.

According to yet another embodiment, calculating the capacitance may include, when the phase of the voltage applied to the process chamber is 90° or 270°, the resistance is 0Ω to 2Ω, and the frequency of the current is 2 MHz or less, approximating the resistance to 0; and approximating the difference between the reactive reactance and the capacitive reactance to the capacitive reactance to calculate the capacitance.

According to yet another embodiment, measuring the process conditions varied according to the consumption amount of the consumables may include setting a first reference graph in which a variation in capacitance according to the consumption amount of the consumables is represented as a linear function; setting a second reference graph in which process conditions varied according to the consumption amount of the consumables are represented as a linear function; and measuring a variation in process conditions according to the consumption amount of the consumables using the first and second reference graphs.

According to yet another embodiment, after calculating the capacitance, the consumables may be exchanged when the capacitance departs from a set range.

According to yet another embodiment, the varied process conditions may be a flow rate of a process gas introduced into the process chamber, an intensity of the radio frequency power, and a temperature of the process chamber.

### BRIEF DESCRIPTION OF THE DRAWINGS

Example embodiments are described in further detail below with reference to the accompanying drawings. It should be understood that various aspects of the drawings may have been exaggerated for clarity.

FIG. 1 is a cross-sectional view of an apparatus for performing a method of monitoring a semiconductor process in accordance with an example embodiment;

FIG. 2 is a flowchart illustrating a method of monitoring a semiconductor process in accordance with an example embodiment;

FIG. 3 is a flowchart illustrating a method of monitoring a semiconductor process in accordance with another example embodiment;

FIG. 4 is a flowchart illustrating a method of calculating a capacitance using a measured impedance;

FIG. 5 is a flowchart illustrating a method of monitoring a semiconductor process in accordance with still another example embodiment;

FIG. 6 is a graph showing an impedance varied according to time that radio frequency power is applied to a process chamber in a first example embodiment;

FIG. 7 is a graph showing a capacitance varied according to time that a radio frequency power is applied to a process chamber in a second example embodiment;

FIG. 8 is a graph showing a capacitance varied according to the consumption amount of a showerhead of a plasma deposition apparatus; and

FIG. 9 is a graph showing an amount of a process gas varied according to the consumption amount of a showerhead.

### DETAILED DESCRIPTION OF EXAMPLE EMBODIMENTS

Various example embodiments will now be described more fully with reference to the accompanying drawings in which some example embodiments are shown. In the drawings, the thicknesses of layers and regions may be exaggerated for clarity.

Detailed illustrative embodiments are disclosed herein. However, specific structural and functional details disclosed herein are merely representative for purposes of describing example embodiments. This inventive concept, however, may be embodied in many alternate forms and should not be construed as limited to only example embodiments set forth herein.

Accordingly, while example embodiments are capable of various modifications and alternative forms, embodiments thereof are shown by way of example in the drawings and will herein be described in detail. It should be understood, however, that there is no intent to limit example embodiments to the particular forms disclosed, but on the contrary, example embodiments are to cover all modifications, equivalents, and alternatives falling within the scope of the inventive concept. Like numbers refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof. Spatially relative terms, such as “beneath,” “below,” “lower,” “above,” “upper” and the like, may be used herein for ease of description to describe one element or a relationship between a feature and another element or feature as illustrated in the figures. It will be understood that the spatially relative terms are intended to encompass different orientations of the device in use or operation in addition to the orientation depicted in the Figures. For example, if the device in the figures is turned over, elements described as “below” or “beneath” other elements or features would then be oriented “above” the other elements or features. Thus, for example, the term “below” can encompass both an orientation which is above as well as below. The device may be otherwise oriented (rotated 90 degrees or viewed or referenced at other orientations) and the spatially relative descriptors used herein should be interpreted accordingly.

Example embodiments are described herein with reference to cross-sectional illustrations that are schematic illustrations of idealized embodiments (and intermediate structures). As such, variations from the shapes of the illustrations as a result, for example, of manufacturing techniques and/or tolerances, may be expected. Thus, example embodiments should not be construed as limited to the particular shapes of regions illustrated herein but may include deviations in shapes that result, for example, from manufacturing. For example, an implanted region illustrated as a rectangle may have rounded or curved features and/or a gradient (e.g., of implant concentration) at its edges rather than an abrupt change from an implanted region to a non-implanted region. Likewise, a buried region formed by implantation may result in some implantation in the region between the buried region and the surface through which the implantation may take place. Thus, the regions illustrated in the figures are schematic in nature and their shapes do not necessarily illustrate the actual shape of a region of a device and do not limit the scope.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

In order to more specifically describe example embodiments, various aspects will be described in detail with reference to the attached drawings. However, the inventive concept is not limited to example embodiments described.

### First Example Embodiment

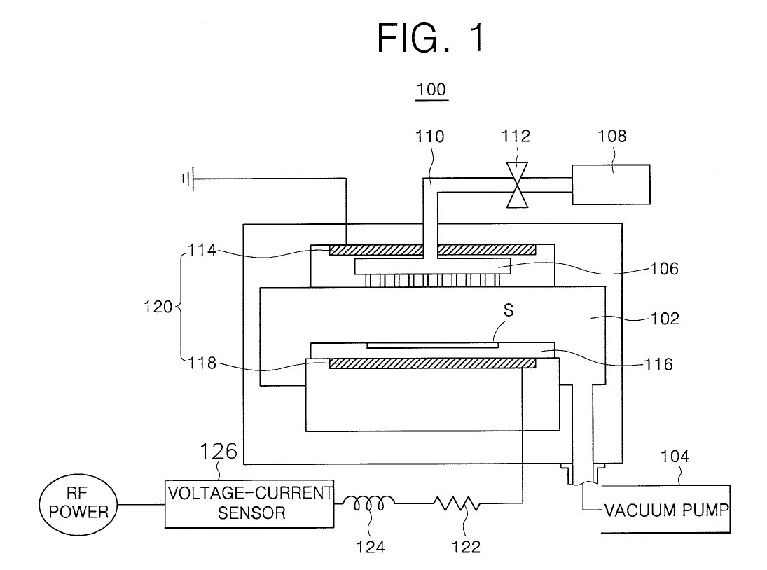

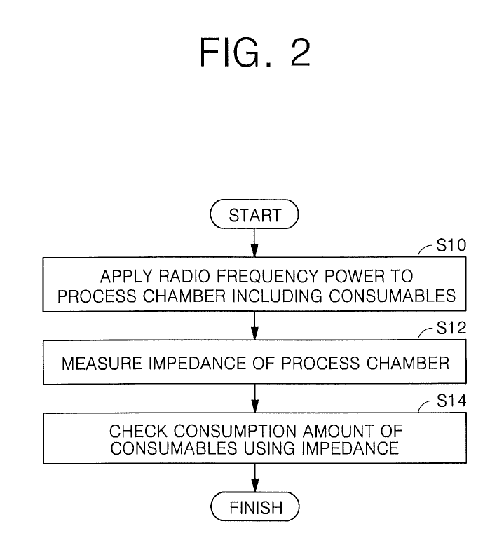

FIG. 1 is a cross-sectional view of an apparatus for performing a method of monitoring a semiconductor process in accordance with an example embodiment, and FIG. 2 is a flowchart illustrating a method of monitoring a semiconductor process in accordance with an example embodiment.

An apparatus 100 shown in FIG. 1 may be an apparatus for depositing a layer on a wafer using plasma. The apparatus 100 includes a process chamber 102, a showerhead 106, a first electrode 114, a chuck 116, a second electrode 118 and an electrical sensor 126 such as a voltage-current (VI) probe. The apparatus 100 may further include an inductor 124 and a resistor 122 disposed between the electrical sensor 126 and the first electrode 114 or the second electrode 118.

The process chamber 102 provide a process space. One side of the process chamber 102 is connected to a vacuum pump 104 to form a vacuum state in the process chamber.

The showerhead 106 may be disposed on an upper part of the process chamber 102. The showerhead 106 may have a plurality of holes (107) for providing a process gas into the process space. One side of the showerhead 106 may be connected to a process gas storage part 108 via a process gas line 110. A valve 112 may be disposed in the process gas line 110 to adjust an amount of a gas provided into the process space.

The showerhead 106 may be one of consumables provided in the apparatus 100. For example, when a radio frequency power is applied to the showerhead 106 newly mounted in the apparatus 100 for 600 hours, diameters of holes 107 formed in the showerhead 106 may be increased by about two times compared to initial diameters. As a result, an amount of the process gas provided into the process space may be increased by about two times.

The first electrode 114 may be disposed on an upper part of the process chamber 102. In accordance with example embodiments, the first electrode 114 may be disposed in the showerhead 106. For example, the first electrode 114 may be connected to ground. As another example, the first electrode 114 may be electrically connected to a predetermined power source to be supplied a predetermined power. Here, the predetermined power source may be a radio frequency power source.

The chuck 116 may be disposed on a lower part of the process chamber 102 to support a substrate S. The chuck 116 can load the substrate S on the upper part, and support and fix the loaded substrate S. The substrate S supported and fixed on the chuck 116 may be disposed to face the holes 107 of the showerhead 106. For example, the substrate S may be fixed on the chuck 116 by vacuum. As another example, the substrate S may be fixed on the chuck 116 by static electricity.

The second electrode 118 may be disposed on a lower part of the process chamber 102. In accordance with example embodiments, the second electrode 118 may be disposed in the chuck 116.

For example, when the first electrode 114 is connected to ground, the second electrode 118 may be electrically connected to a predetermined power source 127 to be applied a predetermined power. As another example, when the first electrode 114 is electrically connected to the predetermined power source 127, the second electrode 118 may be connected to ground. The predetermined power source 127 may be a radio frequency power source.

In example embodiments, the first and second electrodes 114 and 118 are spaced apart a predetermined distance from each other, for example, disposed at upper and lower parts of the process chamber 102. However, in the inventive concept, positions of the first and second electrodes 114 and 118 are not limited.

The resistor 122 and the inductor 124 may be connected between the electrical sensor 126 and the first electrode 114 or the second electrode 118. According to example embodiments, when the first electrode 114 is connected to ground and the second electrode 118 is electrically connected to the predetermined power source 127, the resistor 122 and the inductor 125 may be electrically connected to the second electrode 118. The inductor 124 may be, for example, a coil, etc.

The resistor 122 and the inductor 124 may be electrically connected in series to the predetermined power source such as a radio frequency power source. In addition, the inductor 124 may be disposed between the resistor 122 and the electrical sensor 127.

The electrical sensor 126 such as voltage-current probe may be disposed between the inductor 124 and the predetermined power source 127 such as the radio frequency power source. The electrical sensor 126 can detect voltage and current applied to the process chamber 102. A consumption amount and an exchange time of the consumables of the apparatus 100 may be determined using the detected voltage and current, and a phase of the voltage and a frequency of the current applied to the process chamber 102.

Hereinafter, a method of monitoring the consumption amount of consumables in the plasma deposition apparatus shown in FIG. 1 will be described.

FIG. 2 is a flowchart illustrating a method of monitoring a semiconductor process in accordance with an example embodiment.

Referring to FIGS. 1 and 2, a radio frequency power is applied into the process chamber 102, in which consumables are mounted (S10). The first electrode 114 may be connected ground, and the second electrode 118 may be electrically connected to the radio frequency power source 127.

In this example embodiment, the process chamber 102 may be provide a process space of the apparatus 100 for forming a predetermined layer on a substrate S using plasma. Here, the consumables will be described using the showerhead 106 of the apparatus 100 as an example, but the consumables are not limited to the showerhead 106.

An impedance of the process chamber 102 is measured (S12). The impedance may be measured by a voltage value, a current value and a phase of the voltage applied to the second electrode 118. More specifically, the electrical sensor 126 connected to the process chamber 102 of FIG. 1 can acquire the voltage value, the current value and the phase of the voltage applied to the process chamber 102.

Conventionally, the impedance may be a resistance value, and may be readily acquired by Ohm's law, i.e., by dividing the voltage by the current.

A consumption amount of the consumables can be determined using the measured impedance (S14). For example, in the showerhead 106 of the plasma deposition apparatus 100, the measured impedance is increased as the plasma power application time is increased. Therefore, it is possible to check the consumption amount of the showerhead 106 according to the measured impedance.

### Second Example Embodiment

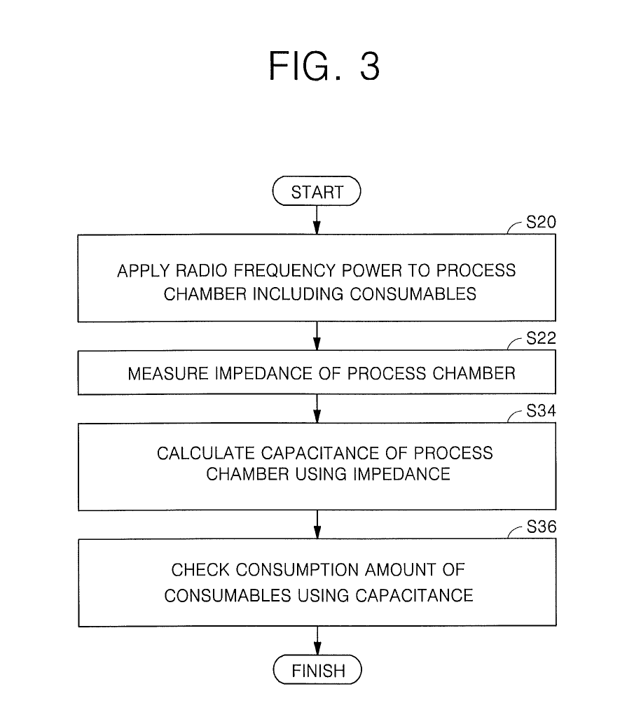

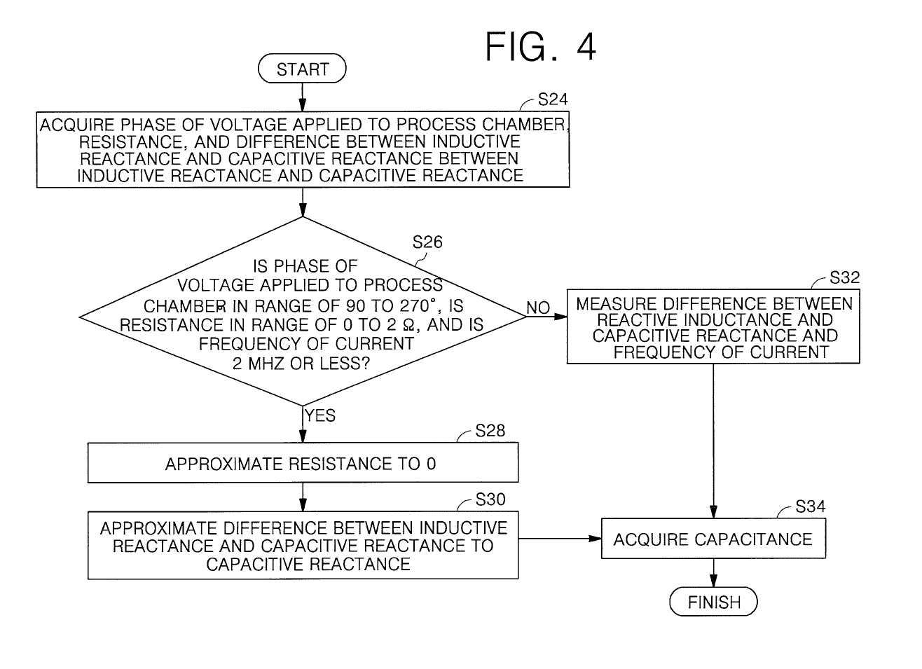

FIG. 3 is a flowchart illustrating a method of monitoring a semiconductor process in accordance with another example embodiment, and FIG. 4 is a flowchart illustrating a method of calculating a capacitance using measured impedance.

Referring to FIGS. 1 and 3, a radio frequency power is applied to the process chamber 102, in which consumables are mounted (S20). The first electrode 114 may be connected ground, and the second electrode 118 may be electrically connected to the radio frequency power source.

In this example embodiment, the process chamber 102 may be provide a process space of a apparatus 100 for forming a predetermined layer on a substrate S using plasma. Here, the showerhead 106 of the apparatus 100 will be described as an example of the consumables. However, the consumables are not limited to the showerhead 106.

An impedance of the process chamber 102 may be measured (S22). The impedance may be measured by a voltage value, a current value, and a phase of the voltage applied to the process chamber.

A capacitance of the process chamber 102 may be calculated using the measured impedance (S34).

The capacitance C of the process chamber 102 may be calculated using a measured impedance Z, a reactance X, a phase Φ of the voltage, and a frequency f of the current (S24). The impedance Z may be acquired using the voltage V and the current I measured by the electrical sensor 126. The reactance X includes an inductive reactance X₁, and a capacitive reactance X_{C}. Referring to FIG. 1, the inductive reactance X₁, may be generated from the inductor, and the capacitive reactance X_{C} may be generated between a first electrode 114 and a second electrode 118. The frequency f of the current may be measured by the electrical sensor 126.

Calculation of the capacitance C will be described as the following formula.

R=Z×cos Φ

X_{L}−X_{C}=Z×sin Φ

X_{L}=2πf×L (L: Inductance)

X_{C}=1/(2πf×C)

By slightly changing the formula, it is possible to acquire the capacitance C and the inductance L according to the frequency f (S32).

Referring to FIG. 4, when a phase of the voltage applied to the process chamber is substantially 90° to 270°, the resistance is 0Ω to 2Ω, and the frequency of the current is 2 MHz or less, the resistance may be approximate to 0, and a difference between the inductive reactance and the capacitive reactance may be approximate to the capacitive reactance (S26, S28, and S30). Therefore, the formula may be further simplified as follows.

Z=X_{C}=1/(2πf×C)

Therefore, it can be more readily acquired using C=1/(2πf×Z) (S34).

The consumption amount of the consumables may be checked using the calculated capacitance C (S36). For example, in the showerhead 106 of the apparatus 100, the measured capacitance C is reduced as the plasma application time is increased. Therefore, it is possible to check the consumption amount of the showerhead 106 according to the measured capacitance C.

### Third Example Embodiment

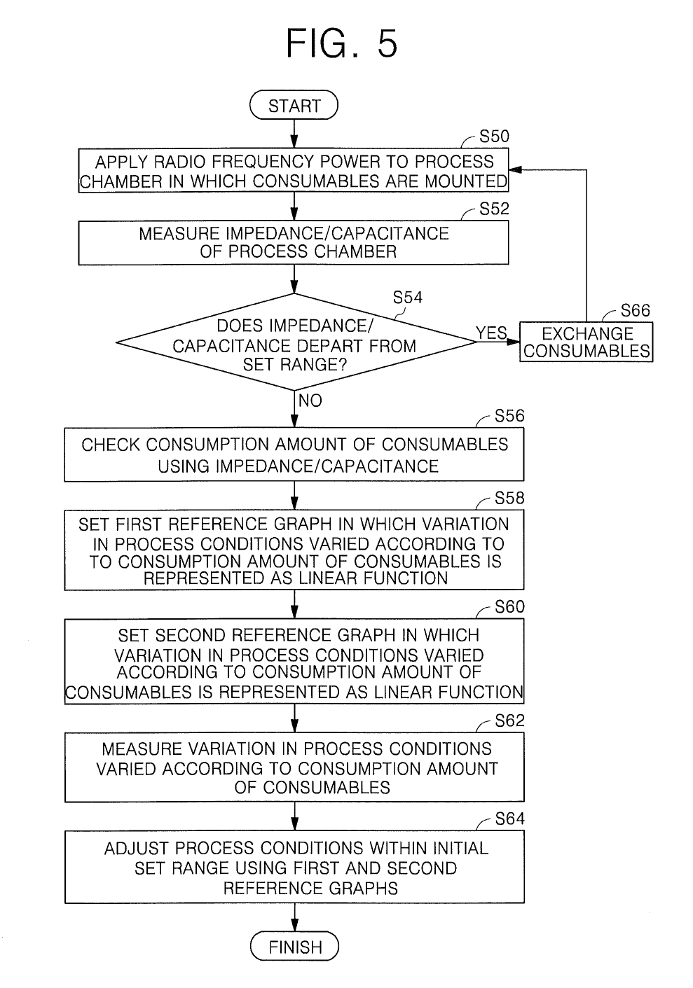

FIG. 5 is a flowchart illustrating a method of monitoring a semiconductor process in accordance with still another example embodiment.

Referring to FIGS. 1 and 5, a radio frequency power is applied to a process chamber 102, in which consumables are mounted (S50). A first electrode 114 may be connected ground, and a second electrode 118 may be electrically connected to the radio frequency power source 127.

In this example embodiment, the process chamber 102 may be provide a process space of a apparatus 100 for forming a predetermined layer on a substrate S using plasma. Here, the showerhead 106 of the apparatus 100 will be described as an example of the consumables. However, the consumables are not limited to the showerhead 106.

An impedance or capacitance of the process chamber 102 may be measured (S52). The impedance and capacitance are the same as those described in first and second example embodiments, and thus detailed description thereof will not be repeated.

In accordance with this example embodiment, it is possible to check whether the measured impedance and capacitance exist within a set value range (S54), When the impedance or capacitance exists within a set range, it is possible to check the consumption amount of the consumables using the impedance or capacitance (S56).

For example, in the showerhead 106 of the apparatus 100, as the plasma application time increases, the measured impedance is increased, and the capacitance is decreased. Therefore, it is possible to check the consumption amount of the showerhead 106 according to the measured impedance or capacitance.

Meanwhile, a first reference graph in which the consumption amount of the consumables according to a variation in the impedance or capacitance is represented as a linear function may be set (S58). In addition, a second reference graph in which process conditions varied according to the consumption amount of the consumables are represented as a linear function may be set (S60). Here, the first and second reference graphs may be preset.

The consumption amount of the consumables may be checked through the impedance and capacitance measured using the first reference graph. Next, a variation in process conditions may be checked through the consumption amount of the consumables using the second reference graph (S62). The varied process conditions may be adjusted to be appropriate to the process conditions within the initial set range (S64).

In accordance with another example embodiment, when the measured impedance and capacitance depart from the set range, it is possible to exchange the consumables (S66).

As described above, it is also possible to check the consumption amount of the consumables in the process apparatus and check a variation in process conditions according to the consumption amount by measuring the impedance or capacitance of the process apparatus. In addition, since the varied process conditions can be adjusted within the initial set range, reliability of the process processed in the process apparatus can be improved.

### Experimental Example

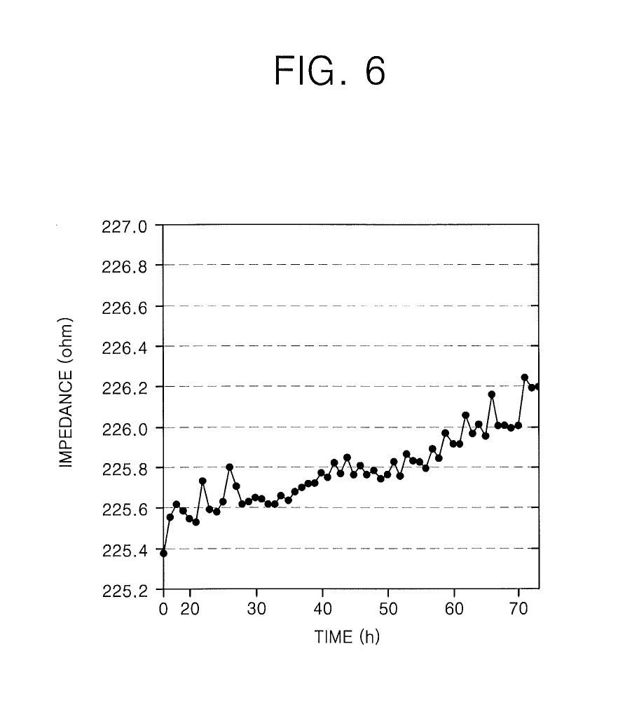

FIG. 6 is a graph showing an impedance varied according to time that a radio frequency power is applied to a process chamber in a first example embodiment.

In FIG. 6, a process apparatus is a plasma deposition apparatus for forming a predetermined layer on a substrate using plasma, and a consumable of the process apparatus is a showerhead.

A horizontal axis of FIG. 6 represents a time that a radio frequency power is applied to the plasma deposition apparatus, and the unit is hours. A vertical axis of FIG. 6 represents an impedance of the plasma deposition apparatus, and the unit is ohms (Ω).

Referring to FIG. 6, the radio frequency power is applied to the plasma deposition apparatus, and the applied power value, a current value, a phase of the power, a resistance, and a frequency of the current are measured using a electrical sensor such as voltage-current probe. An impedance of the plasma deposition apparatus is acquired using the measured power value, the current value, the phase of the power, the resistance, and the frequency of the current. The impedance of the plasma deposition apparatus is continuously measured as a time elapses.

At a time that the showerhead of the plasma deposition apparatus is exchanged with a new one, the impedance of the plasma deposition apparatus is about 225.4Ω. It will be appreciated that the impedance of the plasma deposition apparatus increases as the radio frequency power application time to the plasma deposition apparatus is increased. It will also be appreciated that the impedance of the plasma deposition apparatus was increased to about 226.0Ω when the radio frequency power application time to the plasma deposition apparatus elapsed for about 60 hours.

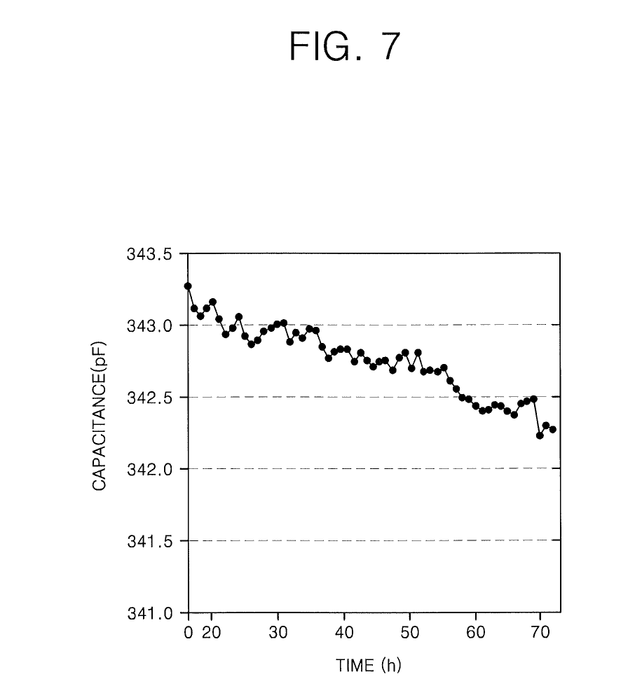

FIG. 7 is a graph showing a capacitance varied according to time that a radio frequency power is applied to a process chamber in a first example embodiment.

In FIG. 7, a process apparatus is a plasma deposition apparatus for forming a predetermined layer on a substrate, and a consumable of the plasma process apparatus is a showerhead.

A horizontal axis of FIG. 7 represents a time that a radio frequency power is applied to the plasma deposition apparatus, and the unit is hours. A vertical axis of FIG. 7 represents a capacitance of the plasma deposition apparatus, and the unit is picofarads (pF).

Referring to FIG. 7, the radio frequency power is applied to the plasma deposition apparatus, and the applied power value, a current value, a phase of the power, a resistance, and a frequency of the current are measured using a electrical sensor such as voltage-current probe. A capacitance of the plasma deposition apparatus is acquired using the measured power value, the current value, the phase of the power, the resistance, and the frequency of the current. The capacitance of the plasma deposition apparatus is continuously measured as a time elapses.

At a time that the showerhead of the plasma deposition apparatus is exchanged with a new one, the capacitance of the plasma deposition apparatus is about 344.5 pF. It will be appreciated that the capacitance of the plasma deposition apparatus increases as the radio frequency power application time to the plasma deposition apparatus is increased. For example, it will be appreciated that the capacitance of the plasma deposition apparatus was decreased to about 343.5 pF when the radio frequency power application time to the plasma deposition apparatus elapsed for about 60 hours.

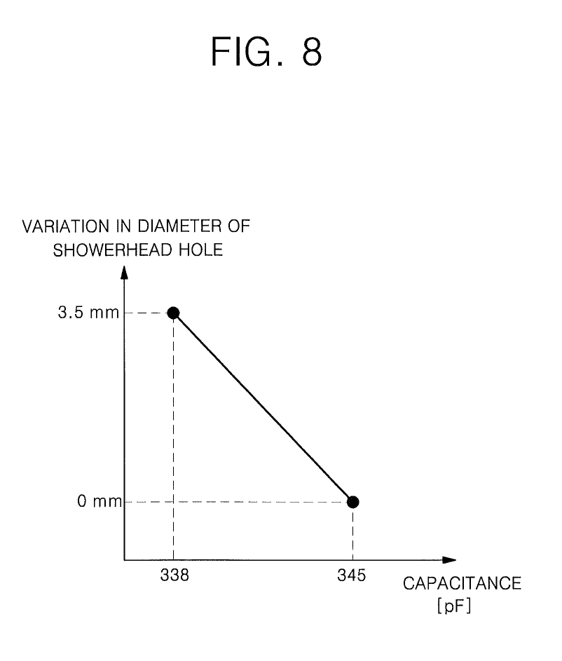

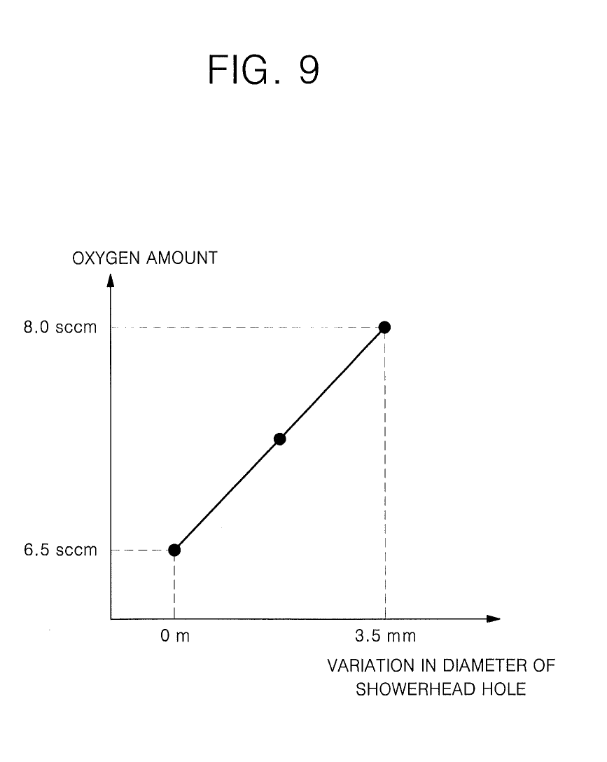

FIG. 8 is a graph showing a capacitance varied according to the consumption amount of a showerhead of a plasma deposition apparatus, and FIG. 9 is a graph showing an amount of a process gas varied according to the consumption amount of a showerhead.

A horizontal axis of FIG. 8 represents a capacitance of the plasma deposition apparatus, and the unit is pF, A vertical axis of FIG. 8 represents a variation in diameter of a hole formed in the showerhead of the plasma deposition apparatus, and the unit is mm.

A horizontal axis of FIG. 9 represents a variation in diameter of the hole formed in the showerhead, and the unit is mm. A vertical axis of FIG. 9 represents an amount of a process gas according to a variation in diameter of the hole formed in the showerhead, and the unit is standard cubic centimeter per minute (seem).

Referring to FIG. 8, the radio frequency power is applied to the plasma deposition apparatus, and the applied power value, a current value, a phase of the power, a resistance, and a frequency of the current are measured using a electrical sensor such as voltage-current probe. The capacitance of the plasma deposition apparatus is acquired using the measured power value, the current value, the phase of the power, the resistance, and the frequency of the current. Diameters of the holes formed in the showerhead of the plasma deposition apparatus at the acquired capacitance are measured. The capacitance of the plasma deposition apparatus and the diameters of the holes of the showerhead are continuously measured as a time elapses. Referring to FIG. 9, a process gas is checked according to the size of the diameters of the holes of the showerhead. The process gas may be oxygen gas.

Referring to FIG. 8, a variation in diameters of the holes at a time the showerhead is exchanged is 0. When the variation in diameters of the holes is 0, the capacitance measured by the plasma deposition apparatus to which the radio frequency is applied is about 345 pF. At a time that the diameters of the holes formed in the showerhead are increased by about 3.5 mm more than initial diameters, the capacitance measured in the plasma deposition apparatus to which the radio frequency power is applied is about 338 pF.

Referring to FIG. 9, a variation in diameters of the holes at the time the showerhead is exchanged is 0. When the variation in diameters of the holes is 0, an amount of oxygen gas provided into the process space of the plasma deposition apparatus through the showerhead is about 6.5 seem. At a time that the diameters of the holes formed in the showerhead are increased by about 3.5 mm more than the initial diameters, an amount of oxygen gas provided into the process space through the showerhead is about 8.0 seem.

Referring to FIGS. 7 to 9, it will be appreciated that the capacitance is reduced as the radio frequency application time to the plasma deposition apparatus is increased, and the diameters of the holes formed in the showerhead is increased as the capacitance is decreased. Increase in diameters of the holes formed in the showerhead means a variation in process gas provided into the process space.

Therefore, by continuously measuring the capacitance of the process chamber as a time elapses using FIGS. 7 to 9, the consumption amount of the consumables can be checked. In addition, by predicting the process conditions varied according to the consumption amount, the varied process conditions can be adjusted within the initial process condition range.

The inventive concept can be modified in various types without departing from the spirit of the inventive concept, not limited to the above example embodiments. For example, the inventive concept may be applied to various equipment used in a semiconductor process.

The foregoing is illustrative of example embodiments and is not to be construed as limiting thereof. Although a few example embodiments have been described, those skilled in the art will readily appreciate that many modifications are possible in example embodiments without materially departing from the novel teachings and advantages. Accordingly, all such modifications are intended to be included within the scope of this inventive concept as defined in the claims. In the claims, means-plus-function clauses are intended to cover the structures described herein as performing the recited function, and not only structural equivalents but also equivalent structures. Therefore, it is to be understood that the foregoing is illustrative of various example embodiments and is not to be construed as limited to the specific embodiments disclosed, and that modifications to the disclosed embodiments, as well as other embodiments, are intended to be included within the scope of the appended claims.

What is claimed is:

1. A method of monitoring a semiconductor process, comprising:
preparing a process chamber including first and second electrodes spaced apart from and facing each other;
connecting the first electrode to a ground and connecting the second electrode to a radio frequency power source;
measuring an impedance in the process chamber using a voltage value and a current value at the second electrode; and
checking a consumption amount of consumables in the process chamber using the impedance.

2. The method according to claim 1, further comprising electrically connecting an inductor and a resistor between the second electrode and the radio frequency power source.

3. The method according to claim 2, further comprising, after measuring the impedance,
calculating a capacitance of the process chamber using the impedance; and
checking a consumption amount of the consumables using the capacitance.

4. The method according to claim 3, wherein calculating the capacitance of the process chamber comprises:
acquiring a phase of a voltage applied to the process chamber, a resistance of the resistor, an inductive reactance of the inductor, and a capacitive reactance between the first and second electrodes; and
calculating the capacitance using a difference between the inductive reactance and the capacitive reactance, the phase of the voltage, the resistance, and a frequency of the current.

5. The method according to claim 4, wherein calculating the capacitance of the process chamber comprises:
when the phase of the voltage applied to the process chamber is 90° or 270°, the resistance is 0Ω to 2Ω, and the frequency of the current is 2 MHz or less,
approximating the resistance to 0; and
approximating the difference between the reactive reactance and the capacitive reactance to the capacitive reactance to calculate the capacitance.

6. A method of monitoring a semiconductor process, comprising:
preparing a process chamber including first and second electrodes spaced apart from and facing each other;
connecting the first electrode to a ground and connecting the second electrode to a radio frequency power source;
measuring an impedance in the process chamber using a voltage value and a current value at the second electrode;
checking a consumption amount of consumables in the process chamber using the impedance;
measuring process conditions varied according to the consumption amount of the consumables; and
adjusting the varied conditions within an initial set range.

7. The method according to claim 6, wherein measuring the process conditions varied according to the consumption amount of the consumables comprises:
setting a first reference graph in which a variation in impedance according to the consumption amount of the consumables is represented as a linear function;
setting a second reference graph in which process conditions varied according to the consumption amount of the consumables are represented as a linear function; and
measuring a variation in process conditions according to the consumption amount of the consumables using the first and second reference graphs.

8. The method according to claim 6, further comprising, after measuring the impedance, exchanging the consumables when the impedance departs from the set range.

9. The method according to claim 6, further comprising electrically connecting an inductor and a resistor between the second electrode and the radio frequency power source.

10. The method according to claim 9, further comprising, after measuring the impedance,
calculating a capacitance of the process chamber using the impedance; and
checking the consumption amount of the consumables using the capacitance.

11. The method according to claim 10, wherein calculating the capacitance of the process chamber comprises:
acquiring a phase of a voltage applied to the process chamber, a resistance of the resistor, an inductive reactance of the inductor, and a capacitive reactance between the first and second electrodes; and
calculating the capacitance using a difference between the inductive reactance and the capacitive reactance, the phase of the voltage, the resistance, and a frequency of the current.

12. The method according to claim 11, wherein calculating the capacitance of the process chamber comprises:
when the phase of the voltage applied to the process chamber is 90° or 270°, the resistance is 0Ω to 2Ω, and the frequency of the current is 2 MHz or less,
approximating the resistance to 0; and
approximating the difference between the reactive reactance and the capacitive reactance to the capacitive reactance to calculate the capacitance.

13. The method according to claim 10, wherein measuring the process conditions varied according to the consumption amount of the consumables comprises:
setting a first reference graph in which a variation in capacitance according to the consumption amount of the consumables is represented as a linear function;
setting a second reference graph in which process conditions varied according to the consumption amount of the consumables are represented as a linear function; and
measuring a variation in process conditions according to the consumption amount of the consumables using the first and second reference graphs.

14. The method according to claim 10, further comprising, after calculating the capacitance, exchanging the consumables when the capacitance departs from a set range.

15. The method according to claim 6, wherein the varied process conditions include a flow rate of a process gas introduced into the process chamber, an intensity of a radio frequency power from the radio frequency power source, and a temperature of the process chamber.
